(19) United States
(12) Patent Application Publication
(10) Pub. No.: US 2025/0172438 A1
(43) Pub. Date: May 29, 2025

(54) SEMICONDUCTOR DIE AND CORRESPONDING METHOD

(71) Applicant: Infineon Technologies AG, Neubiberg (DE)

(72) Inventors: Markus GRÖNER, München (DE); Joachim WEYERS, Höhenkirchen (DE); Ahmed MAHMOUD, Freising (DE)

(21) Appl. No.: 18/950,827

(22) Filed: Nov. 18, 2024

(30) Foreign Application Priority Data
Nov. 28, 2023 (DE) 102023133256.2

(51) Int. Cl. G01K 7/01; G01R 19/10; H01L 27/08

(52) U.S. Cl. CPC G01K 7/015; G01R 19/10; H10D 84/221

(57) ABSTRACT

The disclosure relates to a semiconductor die, comprising: a first diode chain having a number n₁ of diode junctions connected in series, where n₁≥1; a second diode chain having a number n₂ of diode junctions connected in series, where n₂≥1; the first diode chain and the second diode chain to be biased with the same current as a temperature sensor, wherein the first diode chain and the second diode chain differ from each other in their respective number n₁, n₂ of junctions and/or in a doping concentration of at least one of the junctions.

### RELATED APPLICATION

This application claims priority to German Patent Application No. 102023133256.2, filed on Nov. 28, 2023, entitled “SEMICONDUCTOR DIE AND CORRESPONDING METHOD”, which is incorporated by reference herein in its entirety.

### TECHNICAL FIELD

The present disclosure relates to a semiconductor die and to a method of measuring a temperature in the semiconductor die.

### BACKGROUND

Measuring the temperature in a semiconductor die may be of interest for development and testing purposes, for example to investigate a new device design or layout. Further, a temperature monitoring can also be implemented in the application, for instance to assure a high reliability and safety features, e.g., in automotive and industry applications. An overtemperature protection can for example be used to protect against overload and slow (high inductance) short circuits.

### SUMMARY

Examples of the present application are directed at a semiconductor die for temperature sensing.

In an embodiment, a semiconductor die comprises a first diode chain with a number n₁, n₁≥1, of diode junctions connected in series and a second diode chain with a number n₂, n₂≥1, of diode junctions connected in series. The diode chains differ from each other in at least one of: their respective number n₁, n₂ of junctions or in a doping concentration of at least one of the junctions. Providing two diode chains to be biased in parallel may allow for a differential readout, wherein the different number and/or doping of the junctions results in a different forward voltage. The voltage difference between the diode chains will depend on the temperature and, vice versa, may be used to probe a temperature value, see in detail below.

Particular embodiments and features are provided in this description and the figures and in the dependent claims. Therein, the individual features shall be disclosed independently of a specific claim category, the disclosure relates to apparatus and device aspects, but also to method and use aspects. If for instance a particular way for sensing the temperature is described, this may relate to a respective method of measuring the temperature and also to a semiconductor die or system configured for such a measurement. In general words, an approach of this application is to provide a semiconductor die with a first and a second diode chain, wherein these diode chains are configured such that, with the same current through the chains, a different forward voltage results.

A respective “diode chain” comprises at least one diode junction or a plurality of diode junctions connected in series. In case of the first and second diode chain differing in their number of junctions, in the second chain the number can be lower per definition (in the sense of a uniform wording). The second diode chain may comprise at least one junction, for example exactly one junction, whereas the first diode chain may comprise at least two junctions, where n₁≠n₂.

Using the first and second diode chain, for instance connected in parallel in the die or in the measurement system, may for instance reduce or even eliminate the impact of parasitic resistive elements. For instance, due to the intrinsic properties of the junctions, also a single diode chain can have a temperature dependent voltage drop and might be used for temperature sensing. Since this measurement is based on the intrinsic properties of the junction, it may be comparably stable in view of process variations. However, parasitic resistive elements in the circuit might influence the accuracy of a sensor with a single diode chain, as the resistive elements may have a temperature dependence themselves (increasing the diode area might increase its relative contribution in the I-V characteristic, but would cost area).

In comparison to using for instance a bipolar transistor, which is located within the bulk material, for temperature sensing, the diode chains may facilitate the integration in the die.

Depending on their design in detail, they may require less or even no active device area, for instance in comparison to a bipolar transistor fabricated in the semiconductor body of the die. Apart from that, a bipolar device may not be available in each technology, in particular not in high voltage or discrete power switch applications. In this respect, the present approach may allow for combining the simplicity of a diode with a differential readout possibility or system.

Assuming a first and second diode chain, one of them having an additional diode D₂, the voltage difference may calculate as

$${V}_{diff} = {V}_{D 2} = {V}_{f , 0} - {k}_{T} ( T - {T}_{0} ) \qquad Equ . 1$$

When the diode chains are biased with the same current, the difference in voltage of both chains is determined by the additional diode D₂, because the terms or contributions resulting from the like elements in both chains cancel out. In more general words, one may directly measure the forward voltage resulting from the difference between the chains, e.g. the forward voltage of the junction or junctions in which the chains differ (for instance in doping and/or number). In other words, any resistive contributions may basically cancel out due to the relative or differential approach, while only the remaining difference based on junction number and/or doping is measured. The present sensing system or method may for instance improve the accuracy, e.g. compared to one single chain, while reducing the material or integration effort, for instance in comparison to an integrated bipolar device.

In an embodiment, a first resistance R₁ of the first diode chain and a second resistance R₂ of the second diode chain are basically equal in magnitude, for instance differ by not more than 10%, 5% or 3%. In particular, the resistances R₁, R₂ may be equal at technically usual accuracy. By having basically the same series resistance in both chains, effects caused from the series resistance may cancel out, so that the difference in voltage is given by the properties of the diode(s) alone. For illustration, assuming n₁=3 and n₂=1, the voltage difference may calculate as

$${V}_{diff} = 2 * {V}_{D} = 2 * {V}_{f , 0} - 2 * {k}_{T} ( T - {T}_{0} ) \qquad Equ . 2$$

The second diode chain may, in addition to the junction, for instance comprise n and p stripe(s) to mimic the series and possibly even contact resistance of the first diode chain, see in detail below. Alternatively or in addition to the alignment of the first and second resistance, a respective conductor line resistance R_{M} may be aligned, so that the conductor lines provided for contacting the first and second diode chain have basically the same resistance (deviation of not more than 10%, 5% or 3%).

In an embodiment, a first semiconductor region with the first chain and a second semiconductor region with the second diode chain have the same length L. In particular, this may even apply when the first and second diode chain have a different number of junctions (n₁≠n₂), wherein having the same length may for instance allow for the same resistance. The length L may respectively be taken in a length direction, e.g. direction of current flow, in which the junctions of the respective diode chain are connected in series.

In an embodiment, the first diode chain has a plurality of first zones and the second diode chain has at least one first zone, wherein the number of first zones in the diode chain differ. However, a summed length L₁₁ of the plurality of first zones of the first diode chain is equal to a summed length L₂₁ of the at least one first zone of the second diode chain. Having basically the same summed length of first zones in each diode chain may result in basically the same resistance of the respective first zones in the two diode chains. Generally, in this disclosure, the first doping type may in particular be n-type.

In an embodiment, the first diode chain has a plurality of second zones and the second diode chain has at least one second zone, wherein the number of second zones in the diode chain differ. However, a summed length L₁₂ of the plurality of second zones of the first diode chain is equal to a summed length L₂₂ of the at least one second zone of the second diode chain. Having basically the same summed length of second zones in each diode chain may result in basically the same resistance of the second zones in the two diode chains. Generally, in this disclosure, the second doping type may, for example, be p-type.

A diode chain having at least two junctions connected in series may comprise a plurality of first zones and second zones arranged alternately, e.g. along the length direction. For the series connection, e.g. to obtain diodes with the same orientation, each second junction may be bridged by a conductive bridge, for instance in a metallization layer above. In an embodiment, the first and second diode chain differ in their number of junctions but have the same number of conductive bridges between the first zones and second zones. Having the same number of conductive bridges may allow for adjusting the same resistance in the chains, even considering a contact resistance, for instance metal-semiconductor contact resistance.

For illustration, assuming that the number n₁ of junctions of the first diode chain is greater than the number n₂ of junctions of the second diode chain, n₁>n₂, the first diode chain may comprise (n₁−1) conductive bridges connecting the junctions in series. Then, the second diode chain may be provided with the same number (n₁−1) of metal bridges to align the contact resistance, even though a smaller amount (n₂−1) of metal bridges would suffice for the series connection of the smaller amount n₂ of junctions.

In an embodiment, the semiconductor die additionally comprises a semiconductor device. The semiconductor device may have a load terminal, for instance a source region, at a first side of a semiconductor body. On the first side, that may also be considered as a frontside, a contact structure of the device may be arranged, for example a contact plate (e.g. source plate). The contact structure may comprise at least one metallization layer, for instance on an insulating layer arranged on the first side of the semiconductor body. The semiconductor body may comprise a semiconductor substrate and for instance at least one epitaxial layer. In general, the diode chain or chains may be integrated into the semiconductor body, for example in an epitaxial layer, in particular in an uppermost epitaxial layer which forms the first side of the semiconductor body.

In a particular embodiment, however, the diode chain or chains are arranged on the first side of the semiconductor body, in particular on an insulating layer disposed on the first side of the semiconductor body. Placing the diode chain above the semiconductor body may allow for placing the sensor in the active area of the device without significantly affecting the function or reducing the semiconductor area available for the device. In other words, the device has not to be interrupted for placing the diode chains laterally inside the active area, which may also be relevant for the temperature measurement as such (an interruption of the device might distort the temperature profile).

In addition to the (first) load terminal at the first side of the semiconductor body, the device may comprise a second load terminal, for instance a drain region. Depending on the device type, the second load terminal may be arranged at the first side of the semiconductor body as well, e.g. in case of a lateral device. Alternatively, it may be arranged at a second side of the semiconductor body, vertically opposite to the first side. In addition to the load terminals, the device may comprise a control terminal, for instance a gate region to control a current flow between the load terminals. In general, the device may be a bipolar or IGBT device (having for instance an emitter and a collector), a JFET, and/or a transistor device having a source and a drain region.

In an embodiment, the first and second diode chain are respectively formed in a polysilicon layer arranged on the first side of the semiconductor body. In detail, the polysilicon layer may for instance be deposited onto the insulating layer arranged on the first side of the semiconductor body. In the polysilicon layer, first and second zones may be formed by doping, for instance n- and p-zones arranged alternately in a respective diode chain, see above. In a conductive layer above the polysilicon layer, in particular a metallization layer, the conductive bridges inside each diode chain and/or conductor lines for connecting to each diode chain may be formed.

In an embodiment, the diode chains are arranged, together with the semiconductor device, in an active area of the semiconductor die. Seen in a vertical top view, the active area may be surrounded by an edge termination structure. Seen in a respective vertical cross-section perpendicular to a respective lateral edge of the die, the edge termination structure is arranged laterally between the active area and the respective lateral edge of the die. The active area may be filled up with a plurality of device cells connected in parallel, for instance depending on the required current capabilities.

In an embodiment, the first and second diode chain may be arranged closer to a center than to an edge of the active area. This relates to a vertical top view, wherein the center is the geometric center of the active area. In case that the first and/or second diode chain has a non-neglectable lateral extension with respect to the active area, a center of the respective semiconductor region (first region in case of the first diode chain and second region in case of the second diode chain) may be considered for comparing the position of the respective diode chain to the center of the active area.

Independently of a specific position relative to the center of the active area, the diode chains may be placed rather close to each other. Referring for instance to a mean lateral width of the active area, which may be taken as a mean value of its smallest and largest extension, respectively taken along a line crossing the center of the active area, the first and second diode chain may for instance be placed at a lateral distance of not more than 50%, 40%, 30% or 20% of this lateral width. In detail, the distance between the first and second diode chain may be taken as the lateral distance between their centers (of the first and second semiconductor region, respectively, see above).

In an embodiment, the first and second diode chain may be arranged on a common isotherm. Independently of a particular distance between the diode chains, the temperature on the isotherm may be the same. Particular temperature values may depend on the device characteristic and its operation during use. However, the temperature distribution, e.g. relative temperature profile across the device, may be defined by the device geometry, for instance the size and shape of the active area.

The contact structure of the semiconductor device may in particular comprise a contact pad (load pad), for instance source plate, in an uppermost metallization layer. In an embodiment, the first and second diode chain are respectively connected via conductor lines arranged in a wiring layer below the uppermost metallization layer. In particular, these conductor lines may extend below the contact pad (source plate), namely be covered by the contact pad. In other words, the uppermost metallization layer is not to be interrupted for contacting the diode chains, for instance because the differential approach canceling resistive elements allows for smaller/thinner conductor lines with a higher resistance.

Generally, the uppermost metallization layer may be the sole metallization layer of the contact structure. Alternatively, the contact structure may comprise one or several metallization layers below the uppermost metallization layer, for instance for wiring the control terminal of the device. The conductor lines connecting to the diode chains may be formed in such a metallization layer or, alternatively, for instance in a polysilicon layer.

In an embodiment, a system for measuring a temperature value comprises the semiconductor die, a control circuit and a readout circuit. As detailed below, the control and/or readout circuit may be integrated into the die or provided externally, for instance as a laboratory measurement set up or as another component of a module. Independently of these details, the control circuit is configured for applying a current to the first diode chain and to the second diode chain, for instance to apply the same current to both chains. The readout circuit may be configured for measuring a voltage difference between the first diode chain and the second diode chain, which may be the forward voltage of the junction(s) in which the diode chains differ, see in detail above.

In an embodiment, the control circuit and/or the readout circuit is integrated into the semiconductor die. This may allow for an integrated temperature sensing, in particular overtemperature protection, for example to protect against overload or short circuits.

In an embodiment, the control circuit and/or readout circuit is provided in a separate die, wherein the semiconductor die with the diode chains and the separate die are combined in a module. In the module, the die with the diode chains and the separate die may for instance be mounted to a common board and/or be enclosed by a common housing. The dies may be electrically connected to each other via bondwires, clips or any other connection techniques. The control and readout circuitry may also be distributed between the dies, for instance the control circuit integrated into the die with the diode chains and the readout circuit provided in the separate die, or vice versa.

In an embodiment, a method of measuring a temperature with a semiconductor die, in particular with a semiconductor system, may comprise:
Applying a current, in particular the same current, to the first diode chain and to the second diode chain;
measuring a voltage difference between the diode chains.

For applying the current, a first current source may be provided for the first diode chain and a second current source for the second diode chain, each diode chain having its own current source. Alternatively, one common current source may be provided, for instance with a multiplexer switching repeatedly between the first and second diode chain. The diode chains may be on a common reference potential, and the resulting voltage values may be subtracted from one another to obtain the Vdiff.

In an embodiment, a method of manufacturing the semiconductor die may comprise forming the first and the second diode chain. In particular, forming the first and the second diode chain may comprise:
providing a polysilicon layer doped with a first doping type;
providing a structured mask on the doped polysilicon layer,
implanting the second doping type through openings defined by the mask.

### BRIEF DESCRIPTION OF THE DRAWINGS

Below, the die and other embodiments are discussed in further detail by means of exemplary embodiments. Therein, the individual features can also be relevant in a different combination.

FIG. 1 shows a die with an active area and diode chains in a vertical top view;

FIG. 2 shows a first and a second diode chain in a more detailed view;

FIG. 3 shows a circuit diagram and illustrates a system to measure a temperature with the diode chains of FIG. 2;

FIG. 4 illustrates a possible device arranged in the active area of the die of FIG. 1 in a vertical cross-section;

FIG. 5 shows a first and second diode chain in a slightly different design compared to FIG. 2;

FIG. 6 illustrates possibilities for a lateral arrangement of the diode chains in the active area;

FIGS. 7a, b summarize some method steps.

### PARTICULAR EMBODIMENTS

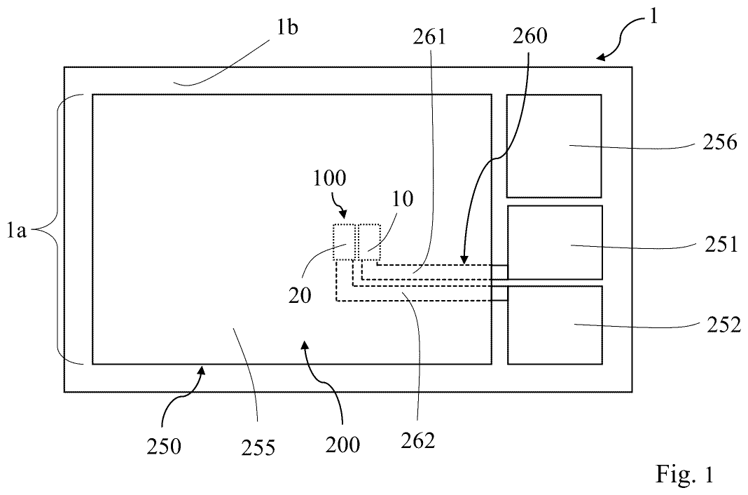

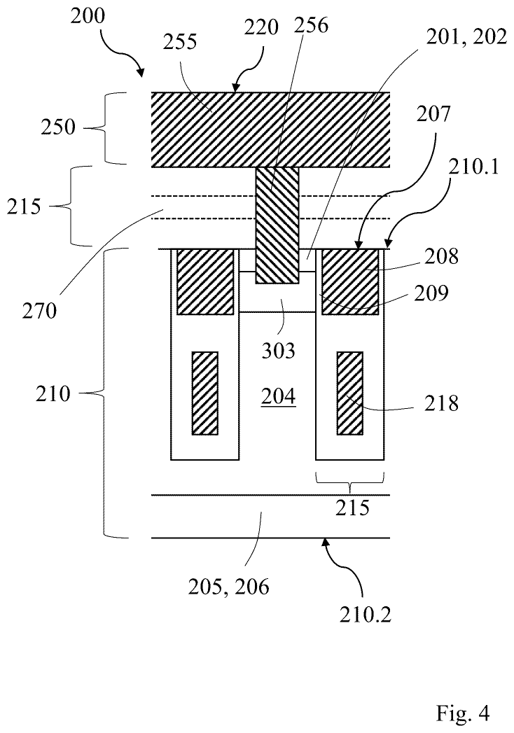

FIG. 1 shows a semiconductor die 1 in a vertical top view. In an active area 1a of the die 1, a semiconductor device 200 is arranged, see FIG. 4 for further details of a possible design. In an uppermost metallization layer 250, a contact pad 255 electrically connected to the device structure below is disposed, for instance a source metallization plate. Aside the contact pad, a control pad 256 connected to a control terminal of the device 200 and temperature sense pads 251, 252 are arranged. The first temperature sense pad 251 connects to a first diode chain 10 and the second temperature sense pad 252 connects to a second diode chain 20.

The diode chains 10, 20 are formed in a polysilicon layer below the contact pad 255 and connected via conductor lines 261, 262 in a wiring layer 260 below the uppermost metallization layer 250. In this embodiment, though the diode chains 10, 20 are arranged in the active area 1a, the contact pad 255 may remain uninterrupted. The active area 1a is surrounded by an edge termination structure 1b shown only schematically here and not referenced in further details.

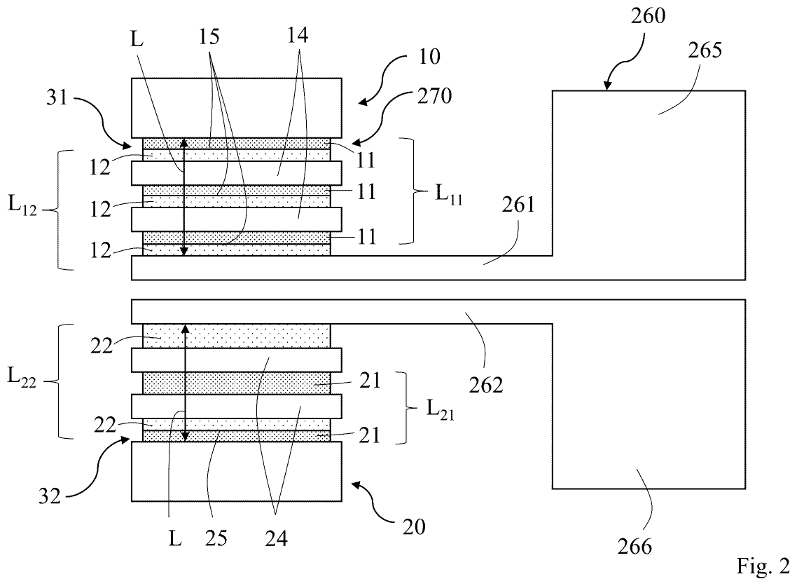

FIG. 2 illustrates the first diode chain 10 and the second diode chain 20 in further detail. The first diode chain 10 comprises a number n₁ of diode junctions 15, wherein n₁=3 in the embodiment shown. The second diode chain 20 comprises a number n₂ of diode junctions 25, wherein n₂=1 in this example. Thus, the diode chains 10, 20 differ in their respective number n₁, n₂ of junctions 15, 25. In the embodiment shown, the junctions 15, 25 are provided with the same doping concentration, alternatively the diode chains 10, 20 might differ in the doping concentration of at least one junction (as an alternative or in combination with the different numbers n₁, n₂).

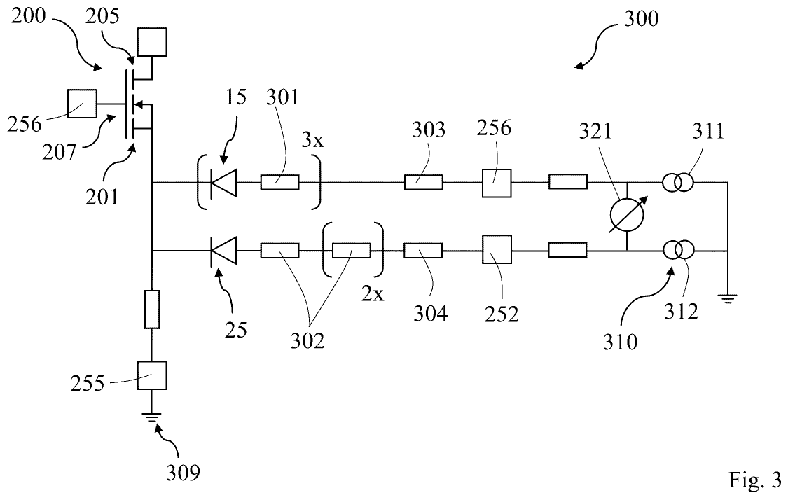

The diode chains 10, 20 are formed in a polysilicon layer 270, in which the first diode chain 10 is arranged in a first semiconductor region 31 and the second diode chain 20 is arranged in a second semiconductor region 32. Though the diode chains 10, 20 differ in their respective number n₁, n₂ of junctions 15, 25, the first and the second semiconductor region 31, 32 have the same length L. This may allow for basically the same sheet resistance in the diode chains 10, 20, that may cancel out in consequence, see FIG. 3 in detail.

The first diode chain 10 comprises a plurality of first zones 11 made of a first doping type and a plurality of second zones 12 made of a second doping type, the first and second zones 11, 12 arranged alternately in succession. In the example shown, the first type is n-type and the second type is p-type. Each second junction, e.g. np-junction in this example, is bridged by a conductive bridge 14 formed above the polysilicon layer 270. In the example shown, the conductive bridges 14 are formed in the wiring layer 260 of the conductor lines 261, 262.

Although having only one diode junction 25 in this example, the second diode chain 20 comprises a plurality of first zones 21 made of the first doping type and second zones 22 made of the second doping type. In addition to bridging the np-junction, the metal bridges 24 of the second diode chain 20 also bridge one pn-junction to provide for the desired number n₂=1 of junctions 25.

A summed length L₁₁ of the first zones 11 of the first diode chain 10, which is obtained by summing up the partial lengths of each first zone 11, is equal to a summed length L₂₁ of the first zones 21 of the second diode chain 20. Likewise, a summed length L₁₂ of the second zones 12 of the first diode chain 10 is equal to a summed length L₂₂ of second zones 22 of the second diode chain 20. Further, in this example, the first and the second diode chain 10, 20 are provided with the same number of conductive bridges 14, 24, which may allow for the same resistance even considering the metal-semiconductor contact resistance.

The conductor lines 261, 262 connect the diode chains to a respective pad 265, 266. The pads 265, 266 are formed in the wiring layer 260 and may connect to the temperature sense pads 251, 252 in the uppermost metallization layer via vertical interconnects which are not shown here. In general, additional conductor lines can be provided to connect the diode chains at their opposite ends. In the example shown, the opposite ends of the diode chains 10, 20 are connected to the contact pad 255 (see FIG. 1) via vertical interconnects not shown here. In operation, the contact pad 255 may be on ground potential.

The circuit diagram of FIG. 3 illustrates a system 300 for measuring a temperature with the first and the second diode chain 10, 20 as illustrated in FIG. 2. In this example, the first diode chain 10 comprises three junctions 15, namely diodes, and the second diode chain 20 comprises one junction 25, namely diode. As discussed above, the same sheet resistances 301, 302 are adjusted for the diode chains 10, 20 so that these resistive elements will cancel out in a differential measurement. The same applies for the resistance 303 of the conductor line 261 and the resistance 304 of the conductor line 262.

Via a control circuit 310, the diode chains 10, 20 can be biased with a current, wherein the same current is applied to both diode chains 10, 20. In the embodiment shown, the control circuit 310 comprises two current sources 311, 312, alternatively one single current source with a multiplexer could be used. The system 300 further comprises a readout circuit 320, e.g. a voltmeter 321, to measure a voltage difference between the two chains 10, 20 or branches. The voltage drop may calculate as

$${V}_{diff} = {V}_{D 1} + 2 * {V}_{D 2} + {I}_{f} * ( {R}_{S 1} + {R}_{S 2} + {R}_{M} + {R}_{ext} ) - {V}_{D 1} - {I}_{f} * ( {R}_{S 1} + {R}_{S 2} + {R}_{M} + {R}_{ext} ) = 2 * {V}_{D 2} \qquad Equ . 3$$

Since the sheet resistances 301, 302 and resistances 303, 304 of the conductor lines are equal and cancel out, so that the voltage difference calculates as

$${V}_{diff} = 2 * {V}_{D} = 2 * {V}_{f , 0} - 2 * {k}_{T} ( T - {T}_{0} ) \qquad Equ . 4$$

At their opposite end, the diode chains 10, 20 are connected to the ground domain 309 via the contact pad 255. In this example, the device 200 is connected as a low side switch, its first load terminal 201 (source region, see below) connected to ground and its second load contact 205 (drain region, see below) connected to the load. The control terminal 207 connects to the control pad 256.

FIG. 4 illustrates one possible device 200 in a vertical cross-section. In this example, the device 200 is a transistor, the first load terminal 201 being a source region 202 and the second load terminal 205 being a drain region 206. In this vertical setup shown, the source region 202 and drain region 206 are arranged at opposite sides 210.1, 210.2 of a semiconductor body 210, wherein a body region 203 and a drift region 204 are disposed vertically in between. The source region 202, drift region 204 and drain region 206 are made of a first doping type, the drift region 204 with a lower concentration compared to the drain region 206, and the body region 203 is made of a second doping type. In the example shown, the first type is n-type and the second type is p-type.

In case of the transistor device, the control terminal 207 may be a gate electrode 208. In this illustrated embodiment, it is arranged in a gate trench 215 etched from the first side 210.1 into the semiconductor body 210. Via a gate dielectric 209, the gate electrode 208 capacitively couples to the body region 203. Optionally, a field electrode 218 may be provided, which capacitively couples to the drift region 204. In the example shown, the field electrode 218 is provided in the same gate trench 215 below the gate electrode 208.

The contact structure 220 disposed at the first side 210.1 of the semiconductor body 210 connects to the first load terminal 201, e.g. source region 202 in this example. In addition to the contact pad 255, it comprises a vertical interconnect 256 which extends through the insulating layer 215.

As illustrated schematically by the dashed lines, the polysilicon layer 270 may be integrated below the uppermost metallization layer 250. In the schematic drawing of FIG. 4, only the uppermost metallization layer 250 is shown, but an additional wiring layer may for instance be provided above the polysilicon layer 270 and below the uppermost metallization layer 250. In a region of the device 200, where a respective diode chain is integrated, the vertical interconnect 265 may be interrupted (source and body region 202, 203 connected in front of or behind the drawing plane).

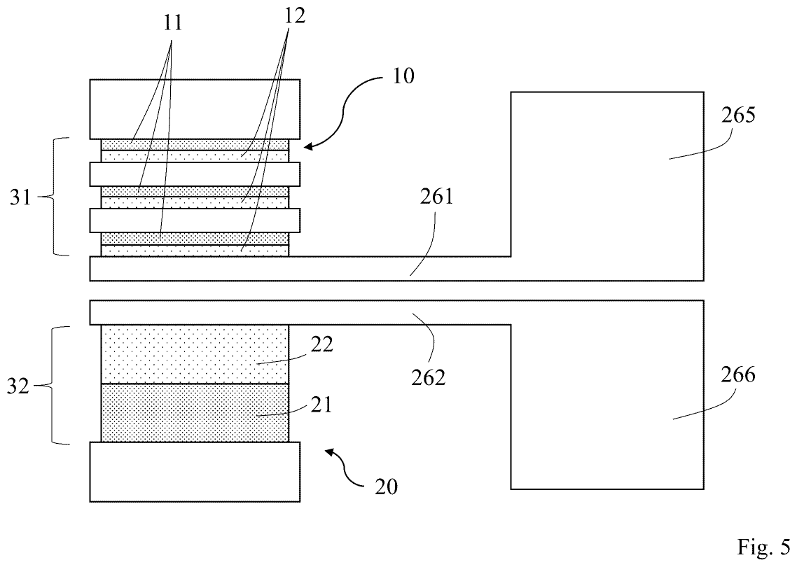

FIG. 5 shows another top view of a first diode chain 10 and a second diode chain 20. As in the example of FIG. 2, the diode chains 10, 20 differ in their respective number n₁, n₂ of junctions 15, 25. Nonetheless, the semiconductor regions 31, 32 are adapted to have the same length L, the first zones 11, 21 and second zones 12, 22 respectively having the same summed length, see in detail above. In contrast to the embodiment of FIG. 2, the diode chains 10, 20 of FIG. 4 are not adapted to have an equal number of conductive bridges.

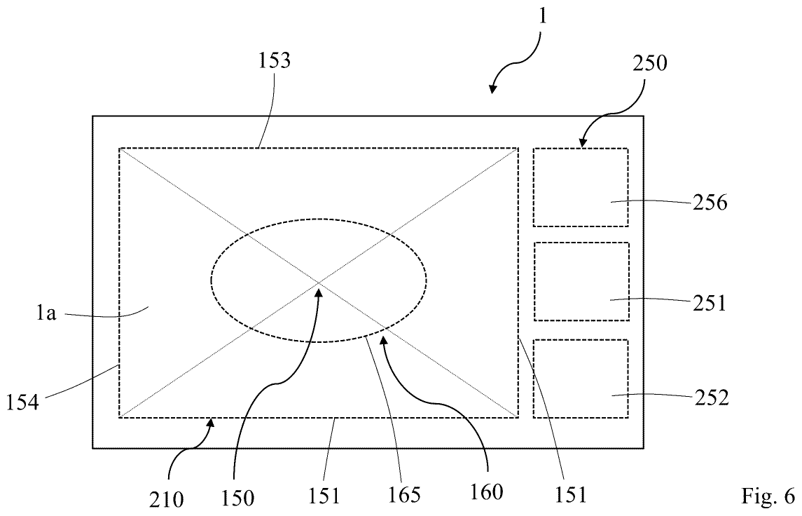

The top view of FIG. 6 shows the complete die 1 again, see the remarks above. In operation, the device 210 heats up which may result in a temperature distribution across the die 1 or in particular active area 1a. Typically, it will heat up more in the center than in edge portions, the temperature profile having for instance a bell-shape. To measure, as far as possible, a sufficiently large or even the maximum value of the temperature, the diode chains 10, 20 may be placed closer to a center 150 of the active area 1a than to a respective edge 155, 152, 153, 154 of the active area 1a. In particular, the diode chains 10, 20 may be placed on a common isotherm 165 so that they are on the same temperature in operation.

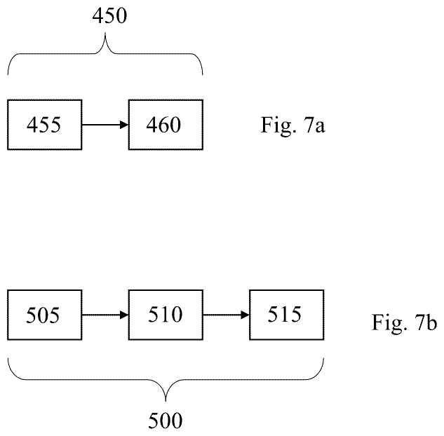

FIGS. 7a, b summarize some method steps. A method of measuring 450 a temperature may in particular comprise applying 455 a current to the diode chains and measuring 460 a voltage difference between the diode chains. A forming 500 of the first and second diode chain may comprise: providing 505 a doped polysilicon layer, providing 510 a structured mask on the polysilicon layer, and implanting 515 an opposite doping type through the mask.

1. A semiconductor die, comprising:
a first diode chain having a first number of diode junctions connected in series; and
a second diode chain having a second number of diode junctions connected in series,
wherein the first diode chain and the second diode chain are biased with the same current as a temperature sensor,
wherein at least one of:
the first number of diode junctions is different from the second number of diode junctions; or
a first doping concentration of at least one diode junction of the first diode chain is different from at least one diode junction of the second diode chain.

2. The semiconductor die of claim 1, the first diode chain having a first resistance and the second diode chain having a second resistance, wherein the first resistance differs less than a threshold amount from the second resistance.

3. The semiconductor die of claim 1, the first diode chain formed in a first semiconductor region and the second diode chain formed in a second semiconductor region, wherein the first semiconductor region and the second semiconductor region have the same length.

4. The semiconductor die of claim 1, the first diode chain having one or more first zones of a first doping type and the second diode chain having one or more second zones, wherein the one or more first zones has a different number of zones than the one or more second zones, wherein a first summed length of the one or more first zones of the first diode chain is equal to a second summed length of the one or more second zones of the second diode chain.

5. The semiconductor die of claim 4, the first diode chain having one or more third zones of a second doping type and the second diode chain having one or more fourth zones of the second doping type, wherein the one or more third zones has a different number of zones than the one or more fourth zones, wherein a third summed length of the one or more third zones of the first diode chain is equal to a fourth summed length of the one or more fourth zones of the second diode chain.

6. The semiconductor die of claim 1, wherein the first diode chain and the second diode chain have the same number of conductive bridges between one or more first zones of a first doping type and one or more second zones of a second doping type.

7. The semiconductor die of claim 1, comprising:
a semiconductor device having a load terminal at a first side of a semiconductor body and a contact structure on the first side of the semiconductor body, wherein the first diode chain and the second diode chain are arranged on the first side of the semiconductor body.

8. The semiconductor die of claim 7, wherein the first diode chain and the second diode chain are respectively formed in a polysilicon layer arranged on the first side of the semiconductor body.

9. The semiconductor die of claim 7, wherein the semiconductor device is arranged in an active area of the semiconductor die and the first diode chain and the second diode chain are arranged in the active area.

10. The semiconductor die of claim 9, wherein the first diode chain and the second diode chain are arranged closer to a center of the active area than to an edge of the active area.

11. The semiconductor die of claim 9, wherein the first diode chain and the second diode chain are arranged on a common isotherm.

12. The semiconductor die of claim 7, the contact structure comprising a contact pad in a metallization layer, wherein the first diode chain and the second diode chain are connected via conductor lines in a wiring layer below the metallization layer.

13. A system for measuring a temperature value, comprising:
a semiconductor die comprising a first diode chain having a first number of diode junctions connected in series and a second diode chain having a second number of diode junctions connected in series;
a control circuit for applying a current to the first diode chain and to the second diode chain; and
a readout circuit for measuring a voltage difference between the first diode chain and the second diode chain.

14. The system of claim 13, wherein the first diode chain and the second diode chain are biased with the same current as a temperature sensor.

15. The system of claim 13, wherein at least one of the control circuit or the readout circuit is integrated into the semiconductor die.

16. The system of claim 13, wherein at least one of the control circuit or the readout circuit is comprised in a second die different than the semiconductor die.

17. The system of claim 16, wherein a module comprises a combination of the semiconductor die and the second die.

18. A method, comprising:
forming a first diode chain, of a semiconductor die, having a first number of diode junctions connected in series; and
forming a second diode chain, of the semiconductor die, having a second number of diode junctions connected in series,
wherein at least one of:
the first number of diode junctions is different from the second number of diode junctions; or
a first doping concentration of at least one diode junction of the first diode chain is different from at least one diode junction of the second diode chain.

19. The method of claim 18, comprising:
applying a current to the first diode chain and to the second diode chain; and
measuring a voltage difference between the first diode chain and the second diode chain.

20. The method of claim 18, wherein at least one of forming the first diode chain or forming the second diode chain comprises:
providing a polysilicon layer doped with a first doping type;
providing a structured mask on the polysilicon layer; and
implanting a second doping type through one or more openings defined by the mask.
